(19) United States
(12) Patent Application Publication
(10) Pub. No.: US 2006/0207752 A1
(43) Pub. Date: Sep. 21, 2006

(54) Micro liquid cooling device

(75) Inventors: Chaucer Chiu, Taipei (TW); Yong-Guo Chen, Shanghai (CN)

Correspondence Address: PEARL COHEN ZEDEK, LLP, 1500 BROADWAY 12TH FLOOR, NEW YORK, NY, 10036, US

(73) Assignee: INVENTEC CORPORATION

(21) Appl. No.: 11/079,339

(22) Filed: Mar. 15, 2005

(51) Int. Cl. H05K 7/20

(52) U.S. Cl. 165/104.33; 165/80.4; 361/699

(57) ABSTRACT

A micro liquid cooling device including a radiator, a thermal conductor, an actuator, and a circular path is proposed. The actuator includes a cavity sealed with a thin film, an inlet diffusion port connected to the cavity, an outlet diffusion port connected to the cavity, a magnetic body connected to the thin film, and a pole acting on the magnetic body, such that circulation of a liquid coolant in the circular path can be effected. By such design of the actuator, vibration and noise can be reduced and reliability can be improved, and thus problems caused by the use of a prior-art technique which employs a piezoelectric pump as an actuation source for the liquid coolant can be solved.

### FIELD OF THE INVENTION

The present invention relates to a design for a heat dissipating device, and more particularly, to a micro liquid cooling device applicable to a heat-producing element such as a semiconductor device for heat dissipation.

### BACKGROUOND OF THE INVENTION

Along with the developments in semiconductor technology, various electronic devices are progressively being miniaturized. For example, the working temperature of a heat-producing element such as a microprocessor is gradually increasing. Thus, the development of a heat dissipating device for heat dissipation of the heat-producing element is a key factor to provide stable operation of the electronic device.

Referring to heat dissipation of a central processing unit of a computer, a heat dissipating device comprising a radiator and a fan is normally employed. The radiator, typically made of aluminum or copper materials, is attached to a surface of the central processing unit, such that heat generated by the central processing unit during operation can be dissipated via the thermal conductivity of the radiator. The fan is provided on the radiator, so that heat transferred to the radiator can be dissipated via air-cooled heat convection. The radiator employed in such method of heat dissipation, however, requires a sufficient heat dissipating surface to be effective. Therefore, the dimensions of the radiator are usually far larger than that of the central processing unit. Moreover, the overall dimensions of the heat dissipating device are further increased after installation of the fan, such that the device cannot be used in a portable electronic device such as a notebook computer.

Referring to FIG. 1, Taiwan Patent No. 509349 has disclosed a liquid cooling heat dissipating device 1 for computer elements, which attempts to improve upon the foregoing prior-art technique. The heat dissipating device 1 comprises a base body 11, a conductor 13 and a mechanical pump 15. The conductor 13 can be tightly attached to a surface of the computer element. The base body 11 affixes to the conductor 13 and is provided with an inlet port and an outlet port. Further, the mechanical pump serves to force a liquid coolant into the inlet port and out of the outlet port to perform heat exchange in an interior of the conductor 13. In comparison to the foregoing air-cooled heat dissipating device, the liquid cooling heat dissipating device proposed in this patent provides a better heat dissipation efficiency. However, as it employs the mechanical pump 15 to circulate the liquid coolant, the overall dimensions are excessively large, such that the method is not applicable to a portable electronic device such as a notebook computer.

Taiwan Patent No. 544568 discloses a liquid cooling system and a personal computer employing such a system, and Taiwan Patent No. 569661 discloses a liquid cooling system having a liquid coolant filling structure and an electronic device employing such a system. The two foregoing patents both disclose liquid cooling devices which employ a piezoelectric pump as a source to circulate the liquid coolant. In these two cases, such liquid cooling devices are applicable to portable electronic devices such as notebook computers.

Referring to FIG. 2, a prior-art liquid cooling device 2 comprises a piezoelectric pump 21, a circular path 22, a thermal conductor 23, a radiator 24, and a storage container 25. The circular path 22 serves to circulate a liquid coolant. The thermal conductor 23 serves to absorb heat generated by a heat-producing element. The piezoelectric pump 21 serves to circulate the liquid coolant using the circular path 22, so as to supply the liquid coolant for the thermal conductor 23. The radiator 24 is used to dissipate heat transferred to the liquid coolant from the thermal conductor 23. Furthermore, a fan can be installed to improve the heat dissipation efficiency. Finally, the storage container 25 serves to supply the liquid coolant. As the foregoing piezoelectric pump 21 has a thickness of approximately 5 mm and the radiator 24 can be an aluminum plate or a copper plate designed with a large surface area and a thickness smaller than 3 mm, such a cooling device is applicable to a portable electronic device such as a notebook computer.

The foregoing liquid cooling device 2 employs the piezoelectric pump 21 as a source to actuate the liquid coolant. The piezoelectric pump 21 changes the volume of a pump chamber using a piezoelectric actuator, such that the liquid coolant can be drawn into the pump chamber and then propelled out of the pump chamber. Additionally, movable check valves which are opened or closed due to pressure differences need to be provided in pipes connected to the inlet side and the outlet side of the pump chamber. However, as the movable check valves need to be provided in the pipes, an extra cost is incurred and extra space is required. Moreover, vibration and noise are produced as the movable check valves open or close, so as to reduce the reliability of actuation of the liquid coolant and applicability to electronic devices.

The problem to be solved here, therefore, is to provide a micro liquid cooling device which is capable of solving the problems caused by using the piezoelectric pump as an actuation source for the liquid coolant, so as to eliminate prior-art drawbacks such as vibration and noise, reduced reliability, and increased costs and space requirements.

### SUMMARY OF THE INVENTION

In light of the above prior-art drawbacks, a primary objective of the present invention is to provide a micro liquid cooling device which is capable of reducing vibration and noise.

Another objective of the present invention is to provide a micro liquid cooling device which is capable of improving reliability.

A further objective of the present invention is to provide a micro liquid cooling device with no check valves, so as to reduce space required and decrease cost.

In accordance with the above and other objectives, the present invention proposes a micro liquid cooling device for dissipating heat generated by at least a beat-producing element. The micro liquid cooling device comprises a radiator; a thermal conductor for receiving heat transferred from the heat-producing element; an actuator having a cavity sealed with a thin film, an inlet diffusion port connected to the cavity, an outlet diffusion port connected to the cavity, a magnetic body connected to the thin film, and a pole acting on the magnetic body; and a circular path for circulating a liquid coolant from the outlet diffusion port to the inlet diffusion port via the thermal conductor and the radiator.

The foregoing thin film is a film characterized with a high ductility. More preferably, the thin film can be a high polymer film such as a polyethylene film.

An inner aperture of the inlet diffusion port connected to the cavity is larger than an outer aperture of the outlet diffusion port. More preferably, the inlet diffusion port can be a funnel-shaped inlet.

An inner aperture of the outlet diffusion port connected to the cavity is smaller than an outer aperture of the outlet diffusion port. More preferably, the outlet diffusion port can be a funnel-shaped nozzle.

The magnetic body can be a permanent magnet. More preferably, the permanent magnet can be a thin film structure or a thin layered structure. The pole acting on the magnetic body can be an electric coil for providing intermittent magnetic attraction or continuous magnetic attraction and repulsion.

The circular path can be a pipe. More preferably, the pipe can be a metal pipe characterized with thermal conductivity.

The thermal conductor can directly contact and absorb heat from the heat-producing element. More preferably, the thermal conductor can be a lid structure provided on the heat-producing element, or alternatively, can be a flat structure covering the heat-producing element.

Furthermore, a storage container connected to the circular path can be provided for supplying liquid coolant. More preferably, the storage container can be a water tank.

Accordingly, referring to the micro liquid cooling device proposed in the present invention, a pole such as an electric coil is employed to result in upward and downward movement of the thin film of the cavity, so as to generate actuation force. Then, the direction of the actuation is controlled by the design of the inlet diffusion port and the outlet diffusion port, such that not only the reliability can be improved and vibration and noise can be reduced, but also the use of a prior-art moveable check valves can be eliminated. In comparison to the prior-art, as a piezoelectric pump is not required in the present invention, moveable check valves are not necessary. Therefore, cost and required space can be reduced and the reliability can be improved. Additionally, vibration and noise can be reduced because of the design of the inlet diffusion port and the outlet diffusion port. Thus, the present invention is capable of eliminating many prior-art drawbacks, so as to improve on the applicability of such a cooling device.

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention.

### BRIEF DESCRIPTION OF THE DRAWINGS

The present invention can be more fully understood by reading the following detailed description of the preferred embodiments, with reference made to the accompanying drawings, wherein:

FIG. 1 is a schematic diagram showing a heat dissipating device according to Taiwan Patent No. 509349;

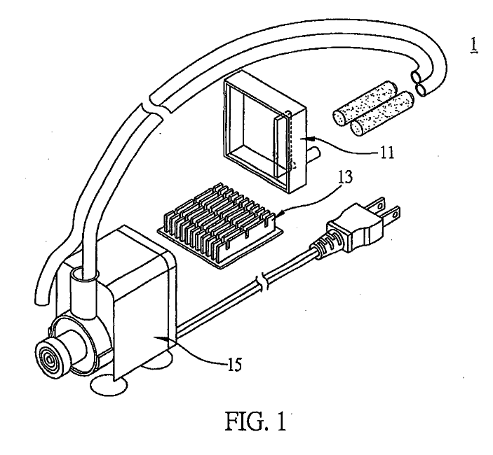

FIG. 2 is a schematic diagram showing the architecture of a liquid cooling device according to the prior-art;

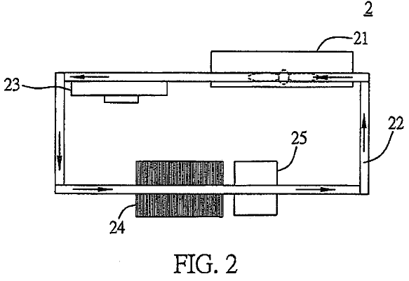

FIG. 3 is a schematic diagram showing architecture of a micro liquid cooling device according to the present invention; and

FIG. 4 is a diagram showing the micro liquid cooling device according to the present invention being applied in a notebook computer.

### DETAILED DESCRIPTION OF THE EMBODIMENTS

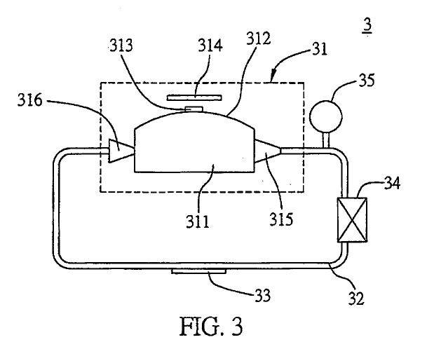

Referring to FIG. 3, the present invention proposes a micro liquid cooling device 3 for dissipating heat generated by at least a heat-producing element. The micro liquid cooling device 3 comprises a micro actuator 31, a circular path 32, a thermal conductor 33, a radiator 34, and a storage container 35. The circular path 32 serves to circulate a liquid coolant. The thermal conductor 33 serves to absorb heat from the heat-producing element. The actuator 31 serves to circulate and supply the liquid coolant to the thermal conductor 33 via the circular path 32. The radiator 34 is used to dissipate heat transferred to the liquid coolant. Furthermore, a fan can be provided to improve the heat dissipation efficiency, and the storage container 35 can serve to supply the liquid coolant.

The actuator 31 is provided with a cavity 311 sealed with a thin film 312, an inlet diffusion port 315 connected to the cavity 31, an outlet diffusion port 316 connected to the cavity 311, a magnetic body 313 connected to the thin film 312 and a pole 314 acting on the magnetic body 313. The thin film 312 is a film characterized with a high ductility and can be a high polymer film such as a polyethylene film. The magnetic body 313 can be a permanent magnet having a thin film structure or a thin layered structure. Furthermore, the pole 314 acting on the magnetic body 313 can be an electric coil for providing intermittent magnetic attraction or continuous magnetic attraction and repulsion, such that the thin film 313 is forced to move upwardly and downwardly to generate an actuation force.

In the present embodiment, the inlet diffusion port 315 is a funnel-shaped inlet located in an inlet side of the cavity 311. An inner aperture of the inlet diffusion port 315 connected to the cavity 311 is larger than an outer aperture of the inlet diffusion port 315. The outlet diffusion port 316 is a funnel-shaped nozzle, and an inner aperture of the outlet diffusion port 316 connected to the cavity 311 is smaller than an outer aperture of the outlet diffusion port 316. Referring to the relationship of position and aperture designed between the inlet diffusion port 315 and the outlet diffusion port 316 and the cavity 311, when the thin film 312 is shifted upwardly due to interaction between the pole 314 and the magnetic body 313, the amount of the liquid coolant drawn in by the inlet diffusion port 315 is more than that forced out by the outlet diffusion port 316. On the contrary, when the thin film 312 is shifted downwardly due to interaction between the pole 314 and the magnetic body 313, the amount of the liquid coolant forced out by the outlet diffusion port 316 is more than that drawn in by the inlet diffusion port 315. Thus, a unidirectional restricting relationship can be provided with regard to the pressure occurring in the internal space of the cavity 311. The actuation direction of the liquid coolant which is drawn in by the inlet diffusion port 315 and forced out by the outlet diffusion port 316 can be well-maintained due to the upward and downward movement of the thin film 312. Therefore, in the present invention, the actuation direction of the liquid coolant can be restricted by the positional relationship of the inlet diffusion port 315 and the outlet diffusion port 316 without requiring a prior-art movable check valve, so as to reduce space and costs required. Furthermore, as it is unnecessary to install the prior-art movable check valves, the reliability of actuation of the liquid coolant can be improved and vibration and noise of actuation of the liquid coolant can be reduced.

The circular path 32 is a pipe such as a metal pipe characterized with thermal conductivity for circulating the liquid coolant. The circular path 32 extends from the outlet diffusion port 316 of the actuator 31 to the inlet diffusion port 315 of the actuator 31 via the thermal conductor 33, the radiator 34, and the storage container 35, such that the liquid coolant can be circulated from the outlet diffusion port 316 to the inlet diffusion port 315 via the thermal conductor 33, the radiator 34 and the storage container 35 corresponding to the cavity 311.

The thermal conductor 33 can directly contact and absorb heat from the heat-producing element and subsequently transfer the heat to the liquid coolant in the circular path 32. The thermal conductor 33 can be made of a material such as aluminum or copper which has a relatively large coefficient of thermal conductivity. Further, the thermal conductor 33 can be a lid structure provided on the heat-producing element, or alternatively, can be a flat structure covering the heat-producing element.

The radiator 34 can absorb the heat of the liquid coolant by directly contacting the circular path 32. Thermal convection between the radiator 34 and the ambient environment can occur spontaneously due to the large heat-dissipating surface area of the radiator 34, such that the heat of the liquid coolant can be dissipated. The radiator 34 can be made of a material such as aluminum or copper which has a relatively large coefficient of thermal conductivity. Moreover, the radiator 34 can be designed to have various shapes or structures for complying with a product's shape in which the micro liquid cooling device is provided. For example, the radiator 34 can be made of an aluminum or copper plate having a large surface area and a thickness smaller than 3 mm, so as to be applicable to a notebook computer.

Furthermore, a storage container 35 is connected to the circular path 32 for supplying the liquid coolant. For example, it can be a water tank which can be opened for adding liquid coolant. Alternatively, it can be a water tank having elastic pores, such that the liquid coolant can be added using a needle.

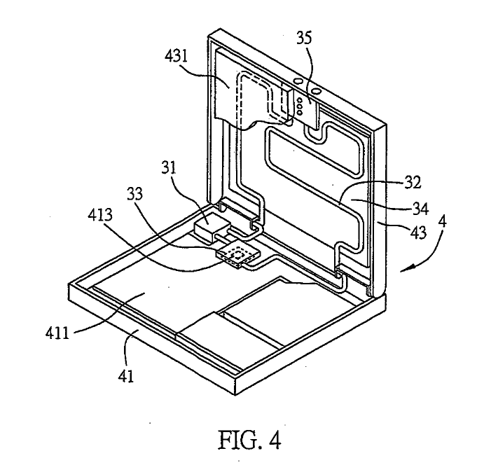

Referring to FIG. 4, when the micro liquid cooling device 3 is applied to a notebook computer 4, the actuator 31 can be provided on a mother board 411 of a computer host 41. Then, the thermal conductor 33 having a lid structure covers and contacts a heat-producing element 413 of a semiconductor device such as a central processing unit. The circular path 32 is routed above the mother board 411 and on a back surface of a liquid crystal panel 431 of a display 43. The radiator 34 is interposed between an outer case of the display 43 and the circular path 32. Moreover, the storage container 35 is connected to the circular path 32 and located on one side of the display 43 (such as a top surface of the display 43 when the display 43 is in the open position).

In FIG. 4, the embodiment of the micro liquid cooling device 3 proposed in the present invention applicable to the notebook computer 4 is illustrated using a specific positional relationship and format. However, referenced positions and the arrangement order of each component are not limited by the present embodiment and can be modified depending on the actual specifications of the notebook computer employing the invention. For example, the modular appearance and location of the actuator 31, appearance and referenced positions of the radiator 34 and the storage container 35, and the path density of the circuitous path 32 can all be modified according to different specifications of the notebook computer or other product employing the invention.

Accordingly, referring to the micro liquid cooling device proposed in the present invention, a pole such as an electric coil is employed to effect an upward and downward movement of the thin film of the cavity, so as to generate actuation forces. Then, the direction of the actuation is controlled by the design of the inlet diffusion port and the outlet diffusion port, such that not only the reliability can be improved and vibration and noise can be reduced, but also the use of a prior-art moveable check valves can be eliminated. In comparison to the prior-art, as a piezoelectric pump is not required in the present invention, moveable check valves iare not necessary. Therefore, cost and required space can be reduced and the reliability can be improved. Additionally, vibration and noise can be reduced because of the design of the inlet diffusion port and the outlet diffusion port. Thus, the present invention is capable of eliminating many prior-art drawbacks, so as to improve the commercial applicability.

It should be apparent to those skilled in the art that the above description is only illustrative of specific embodiments and examples of the present invention. The present invention should therefore cover various modifications and variations made to the herein-described structure and operations of the present invention, provided they fall within the scope of the present invention as defined in the following appended claims.

What is claimed is:

1. A micro liquid cooling device for dissipating heat generated by at least a heat-producing element, the device comprising:
a radiator;
a thermal conductor for receiving heat transferred from the heat-producing element;
an actuator having a cavity sealed with a thin film, an inlet diffusion port connected to the cavity, an outlet diffusion port connected to the cavity, a magnetic body connected to the thin film, and a pole acting on the magnetic body; and
a circuitous path for circulating a liquid coolant from the outlet diffusion port to the inlet diffusion port via the thermal conductor and the radiator.

2. The micro liquid cooling device of claim 1, wherein the thin film is a high polymer film.

3. The micro liquid cooling device of claim 2, wherein the high polymer film is a polyethylene film.

4. The micro liquid cooling device of claim 1, wherein an inner aperture of the inlet diffusion port connected to the cavity is larger than an outer aperture of the inlet diffusion port.

5. The micro liquid cooling device of claim 4, wherein the inlet diffusion port is a funnel-shaped port capable of drawing in liquid.

6. The micro liquid cooling device of claim 1, wherein an inner aperture of the outlet diffusion port connected to the cavity is smaller than an outer aperture of the outlet diffusion port.

7. The micro liquid cooling device of claim 6, wherein the outlet diffusion port is a funnel-shaped nozzle.

8. The micro liquid cooling device of claim 1, wherein the magnetic body is a permanent magnet.

9. The micro liquid cooling device of claim 8, wherein the permanent magnet is a thin film structure or a thin layered structure.

10. The micro liquid cooling device of claim 1, wherein the pole is an electric coil.

11. The micro liquid cooling device of claim 1, wherein the circular path is a pipe.

12. The micro liquid cooling device of claim 11, wherein the pipe is a metal pipe characterized with thermal conductivity.

13. The micro liquid cooling device of claim 1, wherein the thermal conductor is a lid structure provided on the heat-producing element.

14. The micro liquid cooling device of claim 1, wherein the thermal conductor is a flat structure covering on the heat-producing element.

15. The micro liquid cooling device of claim 1, further comprising a storage container connected to the circular path for supplying the liquid coolant.

16. The micro liquid cooling device of claim 15, wherein the storage container is a water tank.
